(19) United States
(12) Patent Application Publication
(10) Pub. No.: US 2026/0229263 A1
(43) Pub. Date: Aug. 6, 2026

(54) BIT LINE SENSE AMPLIFIER OFFSET CANCELLATION IN MEMORY CIRCUITS

(71) Applicant: Samsung Electronics Co., Ltd., Suwon-si (KR)

(72) Inventor: Daesik SONG, San Jose, CA (US)

(21) Appl. No.: 19/373,697

(22) Filed: Oct. 29, 2025

Related U.S. Application Data
(60) Provisional application No. 63/753,915, filed on Feb. 4, 2025.

(51) Int. Cl. G11C 7/12; G11C 7/04; G11C 7/06; G11C 7/08

(52) U.S. Cl. CPC G11C 7/12; G11C 7/04; G11C 7/062; G11C 7/08

(57) ABSTRACT

A memory circuit includes a first circuit and a second circuit. The first circuit is configured to regulate a first voltage difference between a first bit line (BL) and a second BL at a first instant in a first offset cancellation (OC) interval within an OC period. The first voltage difference is associated with a first threshold mismatch between two or more transistors of a first conductivity type in a first part of a sense amplifier. The second circuit is configured to regulate a temporal voltage inequality at a second instant in a second OC interval. The temporal voltage inequality is associated with a second threshold mismatch between two or more transistors of a second conductivity type in a second part of the sense amplifier. The second circuit regulates the temporal voltage inequality by modifying a control signal that controls the second part.

### CROSS-REFERENCE TO RELATED APPLICATION

This application claims the priority benefit under 35 U.S.C. § 119(e) of U.S. Provisional Patent Application Serial No. 63/753,915 filed on February 4, 2025, the disclosure of which is incorporated by reference in its entirety as if fully set forth herein.

### TECHNICAL FIELD

The disclosure generally relates to memory circuits. More particularly, the subject matter disclosed herein relates to bit line sense amplifier in memory circuits.

### Backgound

The present background section is intended to provide context only, and the disclosure of any concept in this section does not constitute an admission that said concept is prior art.

A bit line sense amplifier (BLSA) is a circuit within a memory circuit that senses and amplifies the signals on the bit lines of the memory. One objective of the BLSA is to detect any difference, or offset, between the bit line and its complement and compensate any errors caused by mismatches in device characteristics due to process and temperature variations. Offset cancellation (OC) is a technique to cancel the offset to improve accuracy and speed in memory accesses.

Techniques in OC has a number of drawbacks. The parasitic capacitances and resistances on the BLs cause a long OC period. This long OC period may lead to overcompensation. In addition, the mismatches may be due to any combination of mismatches due to p-channel devices, n-channel devices, or both. Existing OC techniques are not flexible to accommodate different individual scenarios.

The above information disclosed in this Background section is only for enhancement of understanding of the background of the disclosure and therefore it may contain information that does not constitute prior art.

### SUMMARY

To overcome these issues, systems and methods are described herein for a technique of offset cancellation (OC) in a bit line (BL) sense amplifier. A memory circuit includes a first circuit and a second circuit. The first circuit is configured to regulate a first voltage difference between a first BL and a second BL at a first instant in a first OC interval within an OC period. The first voltage difference is associated with a first threshold mismatch between two or more transistors of a first conductivity type in a first part of a sense amplifier. The second circuit is configured to regulate a temporal voltage inequality at a second instant in a second OC interval within the OC period. The temporal voltage inequality is associated with a second threshold mismatch between two or more transistors of a second conductivity type in a second part of the sense amplifier. The second circuit regulates the temporal voltage inequality by modifying a control signal that controls the second part.

In some embodiments, the first circuit has a turn-on resistance that regulates the first voltage difference by a degeneration effect and the second circuit modifies the control signal by pulling down the control signal to a voltage source. The voltage source may be one of a regulated voltage or a fixed voltage.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system that utilizes a BLSA circuit according to an embodiment.

FIG. 2 is a diagram illustrating a BLSA circuit with dual-interval OC and regulated pull-down voltage source according to an embodiment.

FIG. 3 is a diagram illustrating a sense amplifier according to an embodiment.

FIG. 4 is a timing diagram illustrating the dual-interval OC with regulated pull-down voltage source according to an embodiment.

FIG. 5 is a diagram illustrating a BLSA circuit with dual-interval OC and fixed pull-down voltage source according to an embodiment.

FIG. 6 is a timing diagram illustrating the dual-interval OC with fixed pull-down voltage source according to an embodiment.

FIG. 7 is a diagram illustrating performance curves of the dual-interval OC according to an embodiment.

FIG. 8 is a diagram illustrating a process of the dual-interval OC according to an embodiment.

FIG. 9 is a flow chart illustrating a process of regulating voltage difference in the first interval according to an embodiment.

FIG. 10 is a flow chart illustrating the process of regulating voltage difference in the second interval according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures(including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements. In the following, figures depicting various components, structures, interconnections, configurations, and steps of fabrication, are mainly for illustrative purposes. They are not intended to describe these elements accurately. A cross-sectional representation may be used to refer to a 3D block in a 3D structure. In some cases, relevant parts in a figure are shown clearly while other parts are shown with less sharpness or clarity to avoid confusion and improve contrast and clarity. These parts may be referenced in earlier figures and therefore do not need to be described again. These parts may also have little relationship with the part(s) being described. In addition, the shading of the parts in the figures may not have a consistent design and may be changed to maintain clarity and contrast in the figures. For example, part A may have a light shading in Fig. X but may be heavily shaded in Fig. Y. Moreover, as mentioned above, components in a figure may not be drawn with proper scales.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In some embodiments, a system and a method for offset cancellation for BLSA are disclosed. A memory circuit includes a first circuit and a second circuit. The first circuit is configured to regulate a first voltage difference between a first BL and a second BL at a first instant in a first OC interval within an OC period. In some embodiments, the second BL is complementary to the first BL. The first voltage difference is associated with a first threshold mismatch between two or more transistors of a first conductivity type in a first part of a sense amplifier. The second circuit is configured to regulate a temporal voltage inequality at a second instant in a second OC interval within the OC period. The temporal voltage inequality is associated with a second threshold mismatch between two or more transistors of a second conductivity type in a second part of the sense amplifier. The second circuit regulates the temporal voltage inequality by modifying a control signal that controls the second part.

In some embodiments, the first part includes a first transistor and a second transistor of the first conductivity type that are cross coupled. The second part includes a third transistor and a fourth transistor of the second conductivity type that are connect to the first part. In some embodiments, the first circuit has a turn-on resistance that regulates the first voltage difference by a degeneration effect. The first circuit includes a first control transistor of the second conductivity type connected across the first and second transistors. In some embodiments, the second circuit modifies the control signal by pulling down the control signal to a voltage source. The voltage source is one of a regulated voltage or a fixed voltage. The second circuit may include a second control transistor of the second conductivity type having a first terminal connected to the control signal and a second terminal connected to the voltage source. The temporal voltage inequality is an inequality between a second voltage difference and the first voltage difference. The second voltage difference is the difference between the first BL and the second BL at the second instant. The first conductivity type is a p-channel semiconductor type and the second conductivity type is a n-channel semiconductor type.

Some embodiments provide several advantages. The dual-interval OC includes two OC intervals that may be individually and independently controlled. The feature provides flexibility to provide offset cancellation in any environment. In the first interval, the first circuit may be controlled to adjust the first voltage difference according to variations in process and temperature. Similarly, the voltage source in the second circuit may be selected to provide proper value in response to variations in process and temperature. Therefore, the technique may generate optimum offset voltage on the first and second BLs without compensation issues related to a long OC period.

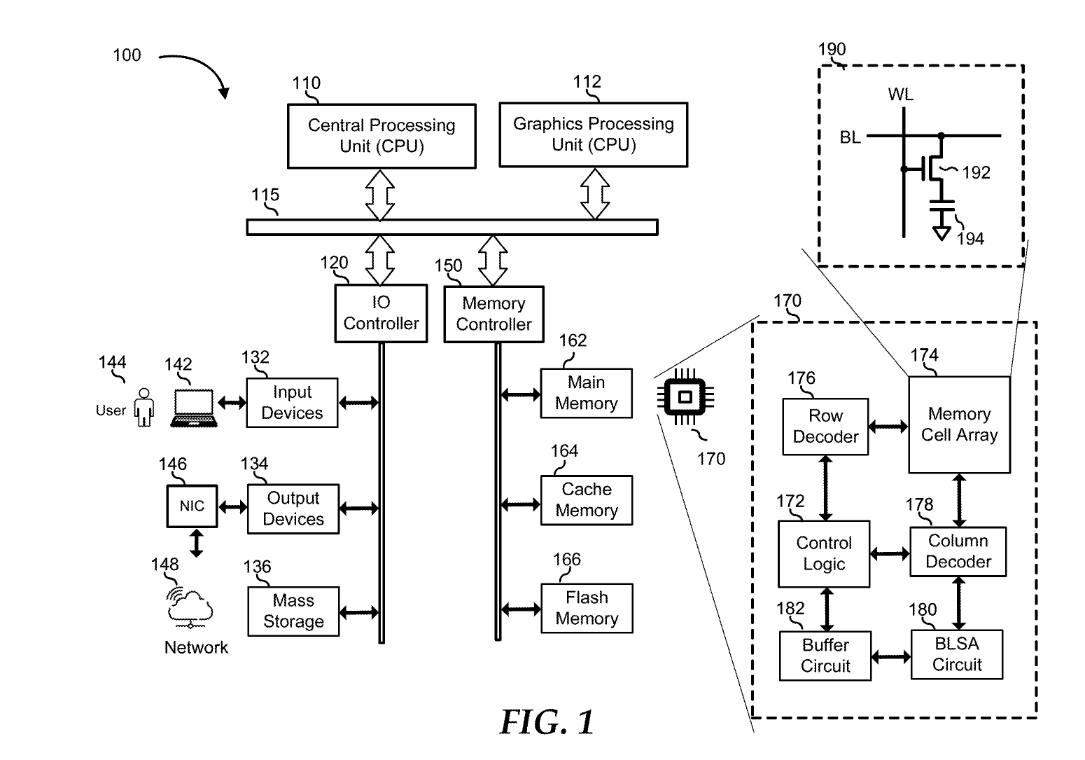

FIG. 1 is a diagram illustrating a system 100 that uses the BLSA circuit according to an embodiment. The system 100 includes a central processing unit (CPU) 110, a graphics processing unit (GPU) 112, an input/output (IO) controller 120, and a memory controller 150. The system 100 may include more or less than the above components. In addition, a component may be integrated into another component. The integration may be partial and/or overlapped. For example, the memory controller 150 and the I/O controller 120 may be integrated into one single controller.

The CPU 110 is a programmable device that may execute a program or a collection of instructions to carry out a task. It may be a host that controls or manages other processors or devices. In particular, the CPU 110 may include applications programming interfaces (APIs), applications, or drivers that are executed by the CPU 110 to perform specified tasks. The CPU 110 may be a general-purpose processor, a digital signal processor, a microcontroller, or a specially designed processor. It may include a single core or multiple cores. Each core may have multi-way multi-threading. The CPU 110 may have simultaneous multithreading feature to further exploit the parallelism due to multiple threads across the multiple cores. In addition, the CPU 110 may have internal caches at multiple levels.

The GPU 112 is a specialized processor designed to perform computationally intensive tasks such as image analysis, graphics rendering, and neural computations. In addition, the GPU 112 may be designed with parallel processing capability, suitable for parallel computations in artificial intelligence (AI) applications including machine learning (ML), large language model (LLM), and neural networks (NN). The GPU 112 may be used to accelerate training and running AI models. It may include multiple computational accelerators or tensor cores which are optimized for basic AI computations such as matrix multiply-accumulate operations. The CPU 110 and the GPU 112 communicate with other devices in the system via a bus 115. The bus 115 may be any suitable bus connecting the CPU 110 or the GPU 112 to other devices. For example, the bus 115 may be a Direct Media Interface (DMI). The bus 115 may also include other custom buses such as bus for the interface to the analog section when the system 188 is used as a mobile device. Additional devices or bus interfaces may be available for interconnections and/or expansion. Some examples may include the Peripheral Component Interconnect Express (PCIe) bus, the Universal Serial Bus (USB), etc.

The I/O controller 120 controls input devices 132, output devices 134, and mass storage 136. The input devices 132 may include a keyboard, a mouse, an image sensor or camera, a game console, and a microphone. Other input devices may also be available such as stylus, joystick, scanner, and light pen. The input devices may also have a user interface to interface to a computer or laptop 142 and/or a user 144. The output devices 134 may include a printer, a monitor or screen, a headset, and a multi-monitor set. When used as a computing device without mobile features, the monitor is a high-resolution display. For games and other multi-display mode, the multi-monitor set provides high-resolution with multiple monitors (e.g., three monitors). When used for mobile communication, the screen provides the primary interface for the user to navigate, access various applications and perform tasks. The screen may use organic light-emitting diode (OLED) (super retina) display with multi-touch or haptic touch feature. The output devices 134 also include a network interface card (NIC) 146 which provides an interface to a network and wireless medium 148. The mass storage 136 may include CD-ROM, hard disk, and solid-state drives (SSDs).

The memory controller 150 controls memory devices such as a main memory 162, a cache memory 164, and a flash memory 166. The memory controller 150 receives a command from the CPU 110 or the GPU 112 for a memory access for a read or write operation. This memory access has a memory address including a row address and a column address that will be used to access a memory cell. The main memory 162 includes random access memory (RAM) including static RAM (SRAM) and dynamic RAM (DRAM) and/or the read-only memory (ROM) and other types of memory. The DRAM may include Synchronous DRAM (SDRAM), Double Data Rate SDRAM (DDR SDRAM) with variations (e.g., DDR2, DDR3, DDR4, DDR5, and DDR6). The main memory 162 may store instructions or programs, loaded from a mass storage device, that, when executed by the CPU 110, cause the CPU 110 to perform operations for a specified task. It may also store data used in the operations. The ROM may be a solid-state drive (SSD) and include instructions, programs, constants, or data that are maintained whether it is powered or not. In one embodiment, the main memory 162 includes a number of memory devices or circuits such as VSDRAM and V-NAND flash memory, or any other memory devices that have memory cells that are stacked vertically to increase storage density. In particular, the main memory 162 includes blocks of memory devices represented by a memory device, circuit, or chip 170.

The memory device, circuit, or chip 170 may include a control logic 172, a memory cell array 174, a row decoder 176, a column decoder 178, a BLSA circuit 180, and a buffer circuit 182. The memory device, circuit, or chip 170 may include more or less than the above components. The control logic 172 includes circuits to generate timing and control signals such as row address strobe (RAS), column address strobe (CAS), write enable (WE), chip enable (CE), OC control signals. The memory cell array 174 includes an array of storage cells, typically organized as a two-dimensional array with rows and columns. A storage cell 190 represents memory cells in the memory cell array 174. The storage cell 190 may be selected or addressed by a word line (WL) that selects the row of the cell and a bit line (BL) that selects the column of the cell. The storage cell 190 includes a transistor 192 and a capacitor 194. The transistor 192 acts as a switch to control access to the capacitor 194, enabling the read or write operations. The capacitor 194 holds an electric charge that represents the logic level of the memory cell.

The row decoder 176 receives the row address of the entire address of the memory cell 190 and decodes the row address to assert a row enable signal to enable the row of the memory cell 190. The column decoder 178 receives the column address of the entire address of the memory cell 190 and decodes the column address to assert a column enable signal to enable the column of the memory cell 190.

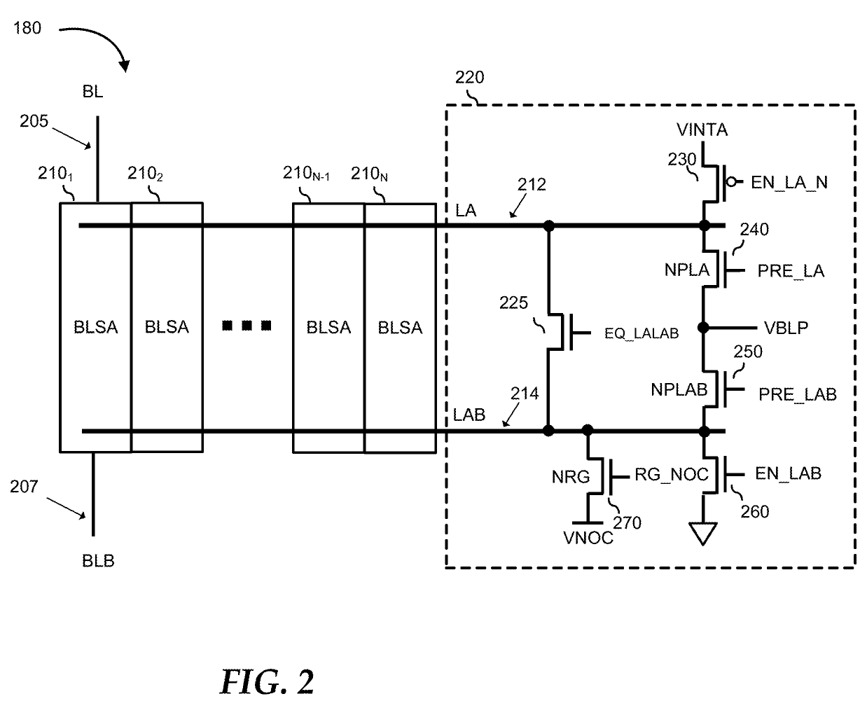

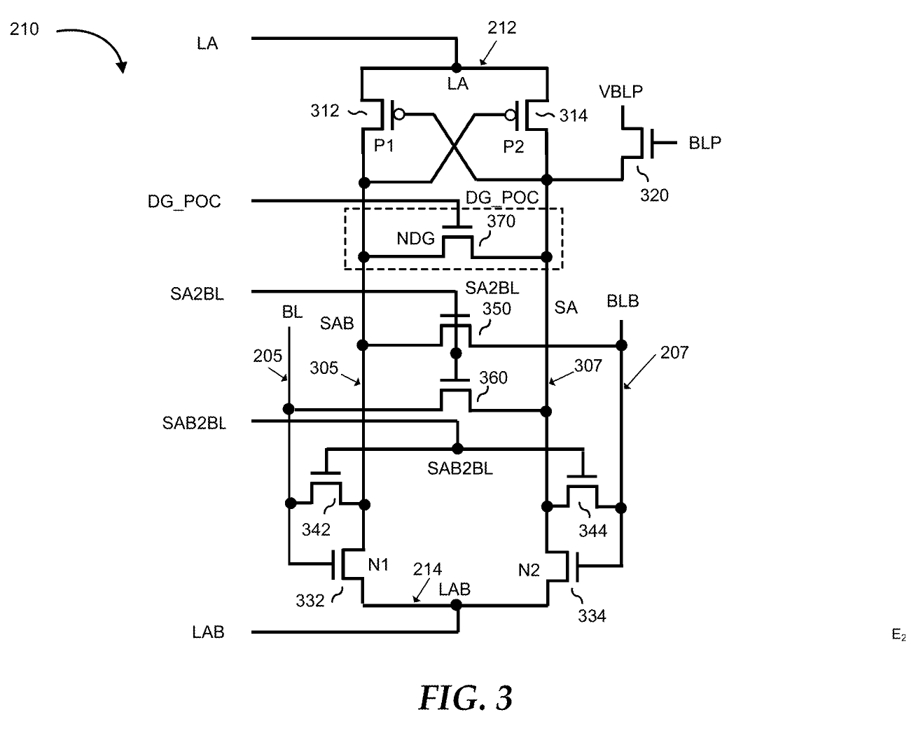

The BLSA circuit 180 includes circuits to sense and amplify the voltage difference generated by the memory cell when being accessed. This allows other circuits to recognize the logic levels of the information stored in the memory cell. Due to the mismatch in threshold voltages of the transistors used in the sense amplifier, there is an offset or error on the signal on the bit lines. Accordingly, the BLSA circuit 180 includes circuits to cancel this offset. In some embodiments, the offset cancellation in the BLSA circuit 180 is implemented by a dual-interval OC that allows individual controls for the p-channel devices and the n-channel devices. This provides flexibility and regulating the voltage difference on the BLs/ The BLSA circuit 180 will be described further in FIGS. 2 and 3. The buffer circuit 182 provides buffer to enable or disable data transmission or reception within the memory circuit 170. This may include interfacing or gating circuits for the data going to or from the memory circuit 170.

FIG. 2 is a diagram illustrating the BLSA circuit 180 shown in FIG. 1 with dual-interval OC and regulated pull-down voltage source according to an embodiment. The BLSA circuit 180 includes N BLSA’s 210₁ to 210_{N} where N is a positive integer and a control block 220. The BLSA 210j’s (j=1, …, N) are connected to the BLs of the memory cell array 174 in FIG. 1 to provide sensing, amplification, and offset cancellation. For clarity, the subscript may be dropped. The BLSA 210 will be described in FIG. 3.

The control block 220 provides additional control functionalities for operations such as pre-charging, offset canceling, charge sharing, pre-sensing, and restoring operations. The operations may be more or less than these operations. The control block 220 includes transistors 225, 230, 240, 250, 260, and 270. The control block 220 may include more or less than the above components.

The transistor 225 has its source and drain terminals connected to signals LA 212 and LAB 213 to control the BLSA sensing operation. The gate of the transistor 225 is EQ_LALAB. When EQ_LALAB is HIGH, the LA 212 and LAB 213 have approximately equal voltages. The BLSA sensing operation is therefore disabled. This disable mode also takes place during pre-charge. The transistor 230 is connected to the LA signal 212 and an internal supply voltage VINTA. Its gate is EN_LA_N. When EN_LA_N is asserted LOW, the LA signal 212 is pulled up to VINTA. The transistors 240 and 250 are involved in the pre-charging operation. The gate control signals are PRE_LA and PRE_LAB. Instead of connecting PRE_LA and PRE_LAB control signals together, they are separated to provide flexibility in individual controls to force the LA and LAB control signals to the voltage level VBLP. The transistor 260 operates to pull down the LAB signal 214. Its gate control signal is EN_LAB.

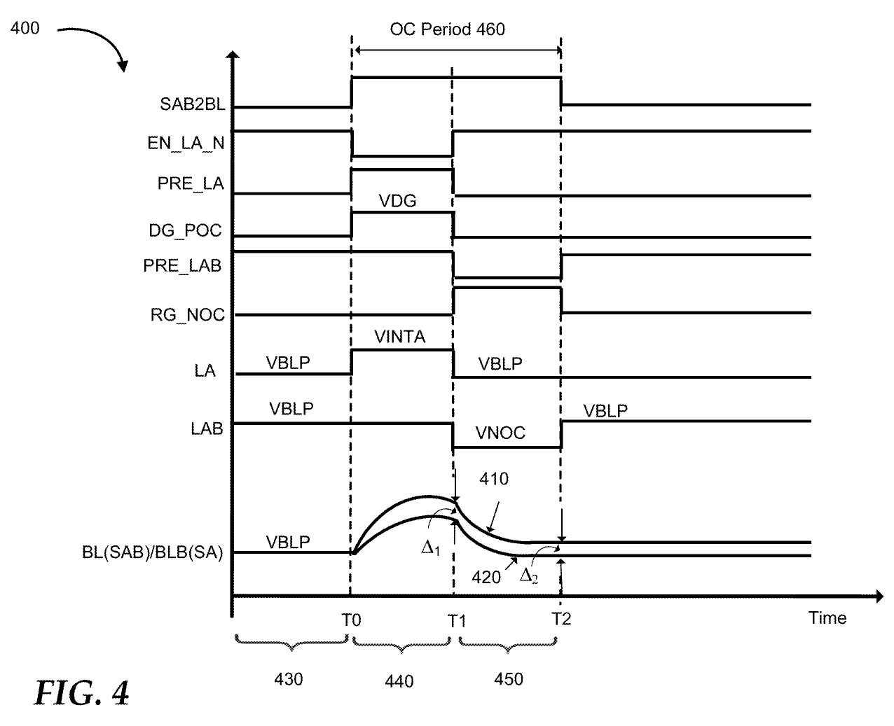

The transistor 270 is connected to the LAB signal 214 and a regulated voltage source VNOC. In this embodiment, the voltage source VNOC may be adjusted for the desired performance in response to variations of temperature and process. The gate control signal for the transistor 270 is RG_NOC. The transistor 270 contributes to the start of the second OC interval during the OC period. The first OC interval is activated by a circuit in the BLSA 210 that will be described in FIG. 3. The first and second OC intervals will be described further in the timing diagram of FIG. 4.

FIG. 3 is a diagram illustrating the sense amplifier BLSA 210 shown in FIG. 2 according to an embodiment. The BLSA 210 includes transistors 312, 314, 320, 332, 334, 342, 344, 350, 360, and 370. The BLSA 210 may include more or less than the above components.

The BLSA 210 is connected to a bit line BL 205 and its complementary BLB 207. The use of differential signaling provides signal sensitivity and improve noise response. The transistors 312 and 314 are of a first conductivity type and the transistors 332 and 334 and of a second conductivity type. The remaining transistors may be of the first or second conductivity as appropriate. In one embodiment, they are of the second conductivity type. In some embodiments, the first conductivity type is p-channel metal oxide semiconductor (PMOS) and the second conductivity type is n-channel MOS (NMOS). Together, the PMOS pair 312 and 314 and the NMOS pair 332 and 334 perform the sensing and amplification functions. The PMOS transistors 312 and 314 may have different threshold voltages due to variations in manufacturing processes, temperature, and other parameters. This difference in threshold voltage, or threshold mismatch, may cause offset noise that will affect the sensing sensitivity. Accordingly, this offset noise needs to be canceled. Similarly, the NMOS transistors 332 and 334 may have different threshold voltages due to variations in manufacturing processes, temperature, and other parameters. This difference in threshold voltage, or threshold mismatch, may cause offset noise that will affect the sensing sensitivity. Similar to the PMOS case, the offset noise from the NMOS pair needs to be canceled. The combined effect of the PMOS and NMOS pairs cause an overall threshold mismatch that needs to be compensated.

In addition, the parasitic effects caused by parasitic capacitances and resistances may create delay that leads to a long OC period. A long OC period may lead to over compensation and result in improper cancellation. Moreover, the overall mismatch may not be the sum of the PMOS mismatch and the NMOS mismatch because one of the PMOS mismatch or the NMOS mismatch may not be present. In other words, the overall mismatch may be any one of the following three scenarios: the sum of the PMOS mismatch and the NMOS mismatch, PMOS mismatch only, and NMOS mismatch only.

The PMOS transistors 312 and 314 are connected in a cross coupled manner. Together, they form a first part of the sense amplifier BLSA 210. One terminal of the PMOS transistor 312 and one terminal of the PMOS transistor 314 are connected to the control signal LA 212. The other terminal of the PMOS transistor 312 is connected to the gate of the PMOS transistor 314 and a signal SAB 305. The other terminal of the PMOS transistor 314 is connected to the gate of the PMOS transistor 312 and a signal SA 307. The cross-coupled transistors 312 and 314 create a positive feedback effect that may be undesirable for mismatch control. As will be discussed later, this undesirable effect may be mitigated or controlled by a degeneration effect accomplished by the transistor 370.

The gate of the NMOS transistor 332 is connected to the BL 205. One terminal of the NMOS transistor 332 and one terminal of the NMOS transistor 334 are connected to the control signal LAB 214. The other terminal of the NMOS transistor 332 is connected to the signal SAB 305. The gate of the NMOS transistor 334 is connected to the BLB 207. Together, the NMOS transistors 332 and 334 form a second part of the sense amplifier BLSA 210. The second part is connected to the first part via the signals SAB 305 and SA 307.

The transistor 320 is connected to a voltage source VBLP and a SA signal 207 to provide VBLP voltage level to the SAB 305, SA 307, and BL 205 and BLB 207 nodes during pre-charge operation. The transistors 342 and 344 have their gates connected to a control signal SAB2BL. The transistor 342 is connected to the BL 205 and the SAB 305. The transistor 344 is connected to the BLB 207 and the signal SA 307. The two transistors 342 and 344 operate to establish an isolation operation. The transistors 350 and 360 have their gates connected to a control signal SA2BL. The transistor 350 is connected to the signal SAB 305 and BLB 207. The transistor 360 is connected to the BL 205 and the signal SA 307. The two transistors 342 and 344 operate for an OC operation control when SAB2BL is asserted HIGH.

The transistor 370 is connected across the cross-coupled PMOS transistors 312 and 314. Its gate is connected to a control signal DG_POC. One terminal of the transistor 370 is connected to the signal SAB 305. The other terminal is connected to the signal SA 307. The control signal DG_POC controls the transistor 370 to create a degeneration effect that mitigates the undesirable positive feedback effect caused by the cross-coupled PMOS transistors 312 and 314. Increasing the DG_POC voltage will reduce the positive feedback until the positive feedback becomes nullified. In general, the degeneration effect is to degrade the output gain on purpose in general amplifier designs.

The operations of the transistors in the BLSA 210 shown in FIG. 2 and FIG. 3 can be further explained in connection with a timing diagram.

FIG. 4 is a timing diagram 400 illustrating the dual-interval OC with regulated pull-down voltage source according to an embodiment. The timing diagram 400 shows the voltage levels of the control signals SAB2BL, EN_LA_N, PRE_LA, DG_POC. PRE_LAB, RG_NOC, LA, and LAB, and the resulting voltage differences BL/BLB or SAB/SA. The vertical axis, the ordinate, is the voltage level for each signal and the horizontal axis, the abscissa, is time.

The voltage difference curves include a curve 410 which corresponds to the BLB (or SA) signal and a curve 420 which corresponds to the BL (or SAB) signal. The time is divided into intervals 430, 440, and 450, marked by the instants T0, T1, and T2. The time instants T0, T1, and T2 mark the instants the control signals may change the level. The interval 430 may correspond to the pre-charge operation. The intervals 440 and 450 form an OC period 460. In this OC period, the interval 440 is the first OC interval which corresponds to the PMOS OC and the interval 450 is the second OC interval which corresponds to the NMOS OC. The intervals 440 and 450 show that the OC can be individually controlled for PMOS mismatch and NMOS mismatch. The voltage difference at the instant T1 is Δ₁ and the voltage difference at the instant T1 is Δ₂.

The transistor 370 in FIG. 3 and the transistor 270 in FIG. 2 form a part of an OC circuit that provides a dual-interval OC. The transistor 370, referred to as a first circuit, is configured to regulate a first voltage difference Δ₁ between the BL and the BLB at a first instant (shown as T1 in the timing diagram) in the first OC interval 440 within the OC period 460. This first voltage difference Δ ₁ is associated with a first threshold mismatch between two or more transistors of a first conductivity type, the PMOS type, in the first part of the sense amplifier BLSA 210. The transistor 270, referred to as a second circuit, is configured to regulate a temporal voltage inequality which is an inequality between a second voltage difference Δ₂ and the first voltage difference Δ₁. The second voltage difference Δ₂ is the difference between the first BL and the second BL at a second instant (shown as T2 in the timing diagram) in the second OC interval 450 within the OC period 460. The temporal voltage inequality is associated with a second threshold mismatch between two or more transistors of a second conductivity type, the NMOS, through the second voltage difference Δ₂ in the second part of the sense amplifier BLSA 210.

The transistor 370 may be referred to as a first control transistor. It has a turn-on resistance that may be adjusted to regulate the voltage difference between BL and BLB at the first instant T1 in the first OC interval. By varying the level of the control signal DG_POC, the turn-on resistance can be adjusted which in turn controls the voltage difference Δ₁ between BL and BLB (or between SAB and SA). This adjustment can be within the threshold mismatch between the PMOS transistors 312 and 314 by the degeneration effect to avoid the cross-coupled PMOS sense amplifier effect. The degeneration effect is one that mitigates the positive feedback effect due to the cross-coupled PMOS transistors 312 and 314 as discussed above. As the voltage level of the transistor 370 increases, the voltage difference Δ₁ at the instant T1 may be reduced to zero which could remove the PMOS OC effect. The voltage of the control signal DG_POC may be set at an optimum level where the voltage difference Δ₁ is exactly to be the same as the threshold mismatch due to the PMOS transistors to provide a perfect OC. It may also be adjusted so that the voltage difference Δ₁ is higher than zero and lower than the threshold mismatch due to the PMOS transistors. Accordingly, the first circuit, the transistor 370, provides an individual control or adjustment of the voltage difference Δ₁ in response to variations in manufacturing processes and/ or temperature.

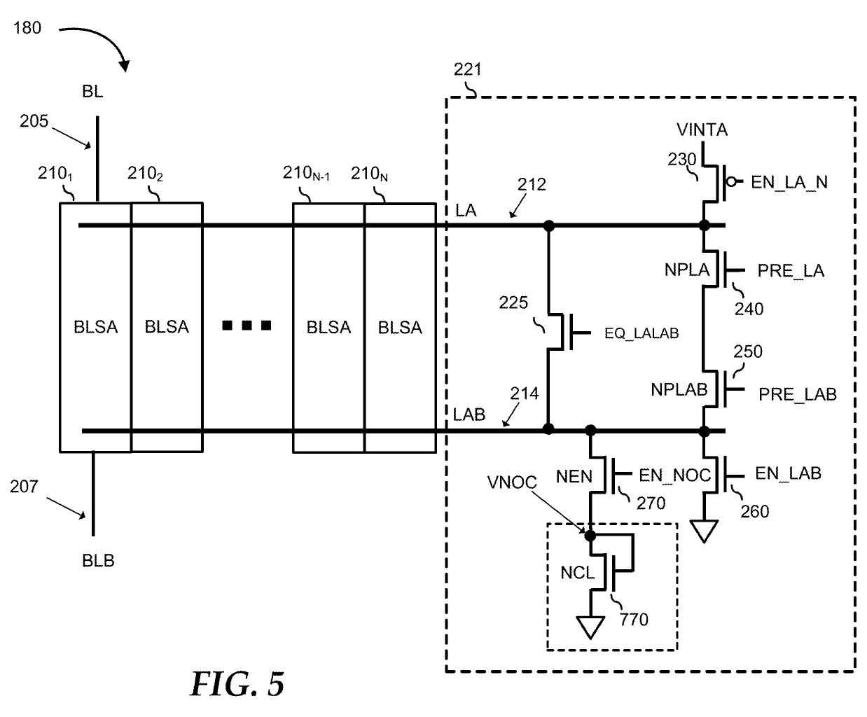

The second circuit, the transistor 270 shown in FIG. 2, provides a pull-down voltage VNOC to be added to the control signal LAB 214. In essence, it modifies the control signal LAB 214 by pulling down the control signal LAB 214 to a voltage source. The transistor 270 may be referred to as a second control transistor of the second conductivity type, the NMOS type, having a first terminal connected to the control signal LAB 214 and a second terminal connected to the voltage source. In some embodiments, the voltage source may be adjustable or regulated as shown in FIG. 2. In some embodiments, the voltage source is fixed as shown in FIG. 5. In the embodiment in FIG. 2, the gate of the transistor 270 is the control signal RG_NOC. When RG_NOC is asserted HIGH, the control signal LAB 214 is pulled down to VNOC and the OC by the NMOS transistors 332 and 334 can start in the second OC interval. By adjusting the voltage level of VNOC, a desired effect can be achieved. When VNOC is high enough, the effect may avoid the NMOS OC effect on the voltage difference Δ₂ at the instant T2. At an optimum level of the voltage VNOC, the effect is such that the inequality or difference between Δ₂ and Δ₁ or ( Δ₂ - Δ₁)to be the same as the NMOS threshold mismatch. By varying the level of VNOC, the inequality or difference (Δ₂ - Δ₁)may be higher than zero and lower than the NMOS threshold mismatch of the transistors 332 and 334.

FIG. 5 is a diagram illustrating the BLSA circuit 180 with dual-interval OC and fixed pull-down voltage source according to an embodiment. The BLSA circuit 180 in FIG. 5 is similar to the BLSA circuit 180 in FIG. 2 except the connection of the transistor 270. The BLSA circuit 180 includes N BLSA’s 210₁ to 210_{N} where N is a positive integer and a control block 221. The control block 221 is similar to the control block 220 in FIG. 2 except the connection of the transistor 270.

In the embodiment shown in FIG. 5, one terminal of the transistor 270 is connected to the control signal LAB 214 as in FIG. 2, but the other terminal is connected to a transistor 770 connected as an ON switch. The gate of the transistor 270 is a control signal EN_NOC. By selecting the appropriate transistor 770, a fixed voltage level VNOC can be established at the other terminal of the transistor 270. This embodiment is therefore simpler than the embodiment in FIG. 2, but it may lack the flexibility of adjusting the control on the LAB signal 214, which affects the voltage inequality or difference (Δ₂ -Δ₁) as explained above.

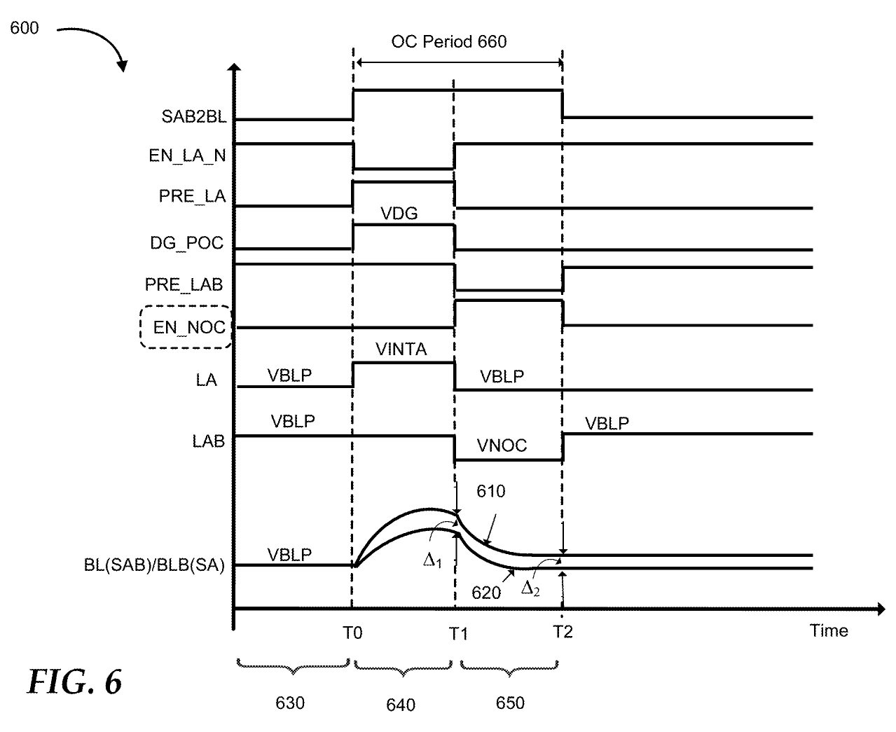

FIG. 6 is a timing diagram 600 illustrating the dual-interval OC with fixed pull-down voltage source according to an embodiment. The timing diagram 600 is identical to the timing diagram 400 with the exception that the control signal EN_NOC replaces the control signal RG_NOC. The curves 610 and 620 correspond to the curves 410 and 420 in FIG. 4, respectively. The three intervals 630, 640, and 650 correspond to the three intervals 430, 440, and 450, respectively. The OC period 660 corresponds to the OC period 460 in FIG. 4. The timing diagram 600 assumes that an appropriate value of the voltage VNOC is selected to provide the desired result.

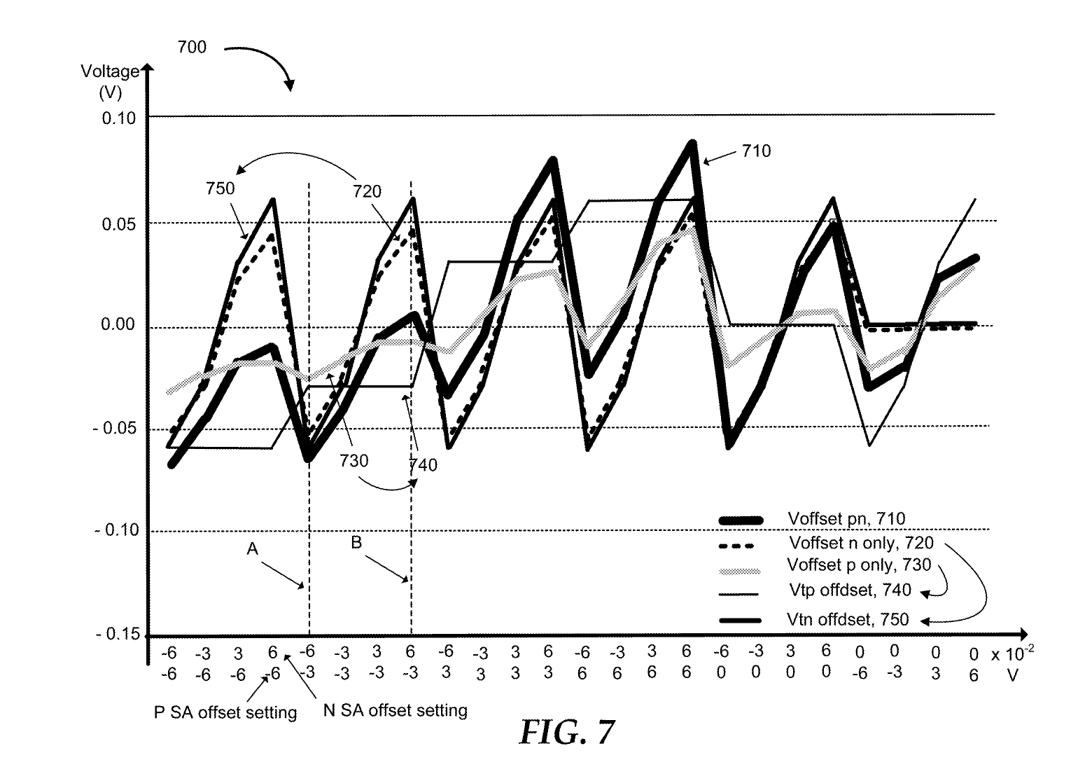

FIG. 7 is a diagram 700 illustrating performance curves of the dual-interval OC according to an embodiment. The diagram 700 include the curves 710, 720, 730, 740, and 750. The abscissa shows the values of the NMOS threshold offset setting (at the upper position) and the PMOS threshold offset setting (at the lower position). The ordinate shows the voltage values. These curves are generated in a simulation to verify the performance of the BLSA circuit having the first and second circuits as described above.

The curve 710 shows the OC result for both PMOS and NMOS parts. The curve 720 shows the OC result for NMOS part only. In other words, the PMOS interval 430 or 630 is skipped. The curve 730 shows the OC result for PMOS part only. In other words, the NMOS interval 440 or 640 is skipped. The curve 740 is the setting of the PMOS threshold. The curve 750 is the setting of the NMOS threshold.

The performance of the OC is shown by examining how close the performance curve follows the corresponding setting. For NMOS, the curve 720 follows very closely to the setting curve 750. For example, at line A, corresponding to Vtn offset = -0.06 V and Vtp offset = -0.03 V, the two curves almost coincide. At line B, corresponding to Vtn offset = 0.06 V and Vtp offset = -0.03, the curve 720 is at about 0.04V while the curve 750 is at 0.06 (Vtn offset). For PMOS, the curve 730 does not follow the corresponding setting curve 740 as closely as the curves 720 and 750, but somewhat closely. For example, at line A while the Vtp offset is -0.03 V, the curve 730 is at about -0.25. At line B while the Vtp offset is -0.03 V, the curve 730 is at about -0.01 V. The composite curve 710 appears to follow the average of the PMOS offset and the NMOS offset.

The performance curves 710, 720, and 730 therefore show that the dual-interval OC in the BLSA circuit 180 using the first and second circuits perform well. In particular, the BLSA circuit 180 allows PMOS and NMOS OC’s in sequential intervals.

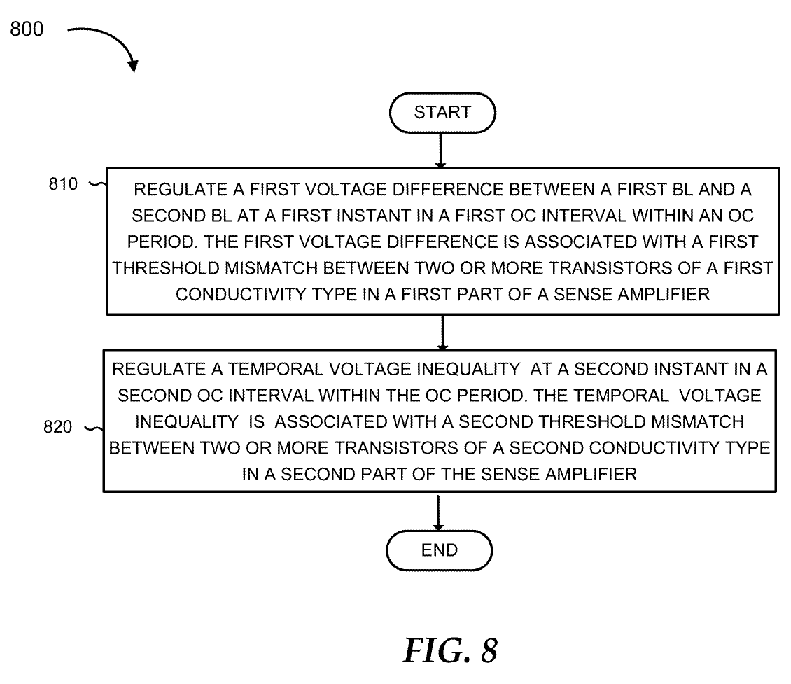

FIG. 8 is a diagram illustrating a process 800 of the dual-interval OC according to an embodiment.

The process 800 regulates a first voltage difference between a first BL and a second BL at a first instant in a first OC interval within an OC period (Process 810). The first instant may correspond to the instant T1 and the first OC interval may correspond to the interval 440 within the OC period 460 in the timing diagram of FIG. 4. In one embodiment, the second BL may be a complementary BL, or complement to the first BL. The first voltage difference is associated with a first threshold mismatch between two or more transistors of a first conductivity type in a first part of a sense amplifier. In one embodiment, the first conductivity type is a PMOS type and the first threshold mismatch is the threshold mismatch between two PMOS transistors like the transistors 312 and 314 in FIG. 3. In one embodiment, the first part includes a first transistor and a second transistor of the first conductivity type that are cross coupled. The first transistor and the second transistor may correspond to transistors 312 and 314, respectively, in FIG. 3. The first part may correspond to the two PMOS transistors 312 and 314 in FIG. 3.

Next, the process 800 regulates a temporal voltage inequality at a second instant in a second OC interval within the OC period (Process 820). The temporal voltage inequality is associated with a second threshold mismatch between two or more transistors of a second conductivity type in a second part of the sense amplifier. In one embodiment, the first conductivity type is a NMOS type and the second threshold mismatch is the threshold mismatch between two NMOS transistors like the transistors 332 and 334 in FIG. 3. The second instant may correspond to the instant T2 and the second OC interval may correspond to the interval 450 within the OC period 460 in the timing diagram of FIG. 4. The second part includes a third transistor and a fourth transistor of the second conductivity type that are connect to the first part. The third transistor and a fourth transistor my correspond to transistors 332 and 334, respectively, in FIG. 3. In one embodiment, the temporal voltage inequality is an inequality between a second voltage difference and the first voltage difference. This temporal voltage inequality may be the voltage difference (Δ₂ - Δ₁) as explained above. In one embodiment, regulating the temporal voltage inequality includes modifying a control signal that controls the second part. The process 800 is then terminated.

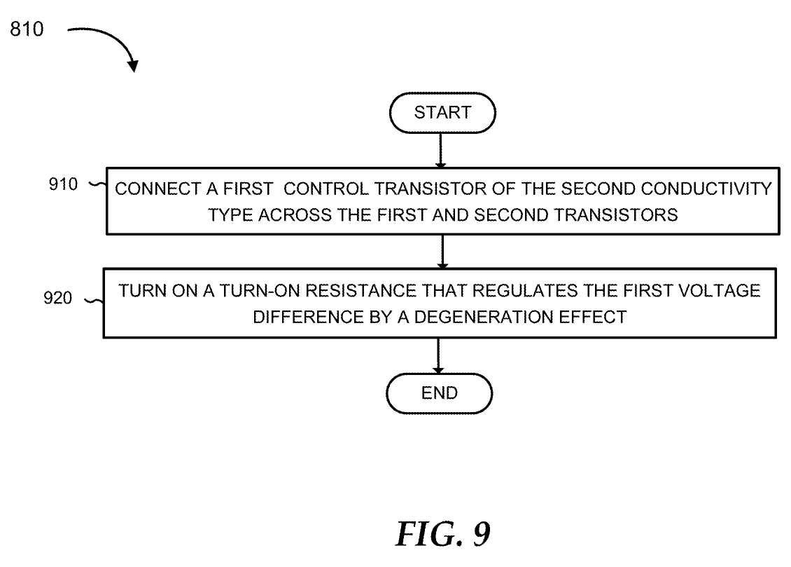

FIG. 9 is a flow chart illustrating the process 810 shown in FIG. 8 of regulating voltage difference in the first interval according to an embodiment.

The process 810 connects a first control transistor of the second conductivity type across the first and second transistors (Process 910). The first control transistor may be the transistor 370 shown in FIG. 3. Next, the process 810 turns on a turn-on resistance that regulates the first voltage difference by a degeneration effect (Process 920). The degeneration effect is to mitigate the undesirable positive feedback effect caused by the cross-coupled transistors as discussed above in connection with FIG. 3 and FIG. 4. The turn-on resistance is the resistance of the transistor 370 when it is turned on, i.e., when the voltage DG_POC at the gate is asserted HIGH. The process 810 is then terminated.

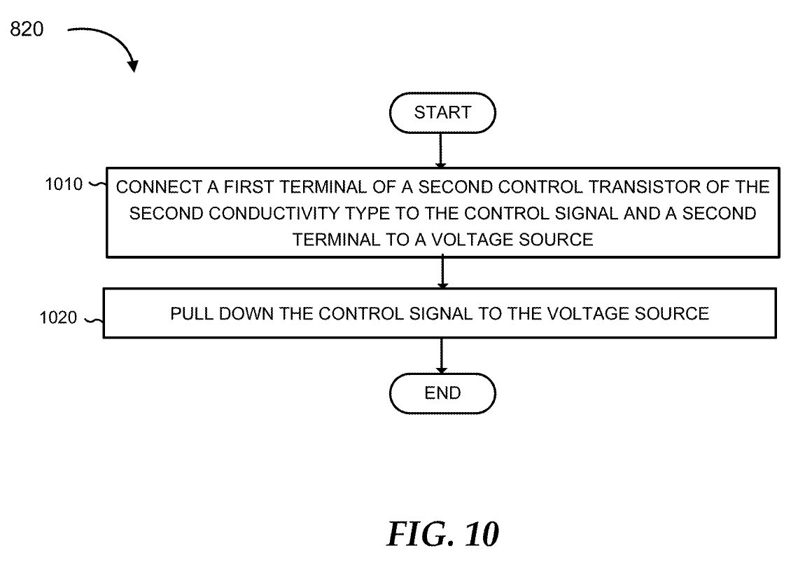

FIG. 10 is a flow chart illustrating the process 820 shown in FIG. 8 of regulating voltage difference in the second interval according to an embodiment.

The process 820 connects a first terminal of a second control transistor of the second conductivity type to the control signal and a second terminal to a voltage source (Process 1010). The second control transistor is the transistor 270 in FIG. 2 or FIG. 5. Next, the process 820 pulls down the control signal to a voltage source (Process 1020). The voltage source may correspond to the voltage VNOC shown in FIG. 2 and FIG. 5. The voltage source may be a regulated voltage or a fixed voltage. The process 820 is then terminated.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, t he scope of claimed subject matter should not be limited to any of the specific exemplary teachings discussed above, but is instead defined by the following claims.

What is claimed is:

1. A device comprising:
a first circuit configured to regulate a first voltage difference between a first bit line (BL) and a second BL at a first instant in a first offset cancellation (OC) interval within an OC period, the first voltage difference being associated with a first threshold mismatch between two or more transistors of a first conductivity type in a first part of a sense amplifier; and
a second circuit configured to regulate a temporal voltage inequality at a second instant in a second OC interval within the OC period, the temporal voltage inequality being associated with a second threshold mismatch between two or more transistors of a second conductivity type in a second part of the sense amplifier,
wherein the second circuit regulating the temporal voltage inequality includes modifying a control signal that controls the second part.

2. The device of claim 1, wherein the first part comprises a first transistor and a second transistor of the first conductivity type that are cross coupled.

3. The device of claim 1, wherein the second part comprises a third transistor and a fourth transistor of the second conductivity type that are connected to the first part.

4. The device of claim 1, wherein the first circuit has a turn-on resistance that regulates the first voltage difference by a degeneration effect.

5. The device of claim 2, wherein the first circuit comprises a first control transistor of the second conductivity type connected across the first and second transistors.

6. The device of claim 1, wherein the second circuit modifying the control signal includes pulling down the control signal to a voltage source.

7. The device of claim 6, wherein the second circuit comprises a second control transistor of the second conductivity type having a first terminal connected to the control signal and a second terminal connected to the voltage source.

8. The device of claim 6, wherein the voltage source is a regulated voltage.

9. The device of claim 1, wherein
the temporal voltage inequality is an inequality between a second voltage difference and the first voltage difference, and
the second voltage difference is a difference between the first BL and the second BL at the second instant.

10. The device of claim 2, wherein the first conductivity type is a p-channel semiconductor type and the second conductivity type is a n-channel semiconductor type.

11. A method comprising:
regulating a first voltage difference between a first bit line (BL) and a second BL at a first instant in a first offset cancellation (OC) interval within an OC period, the first voltage difference being associated with a first threshold mismatch between two or more transistors of a first conductivity type in a first part of a sense amplifier; and
regulating a temporal voltage inequality at a second instant in a second OC interval within the OC period, the temporal voltage inequality being associated with a second threshold mismatch between two or more transistors of a second conductivity type in a second part of the sense amplifier,
wherein regulating the temporal voltage inequality comprises modifying a control signal that controls the second part.

12. The method of claim 11, wherein the first part comprises a first transistor and a second transistor of the first conductivity type that are cross coupled.

13. The method of claim 11, wherein the second part comprises a third transistor and a fourth transistor of the second conductivity type that are connect to the first part.

14. The method of claim 11, wherein regulating the first voltage difference comprises turning on a turn-on resistance that regulates the first voltage difference by a degeneration effect.

15. The method of claim 12, wherein regulating a first voltage difference comprises connecting a first control transistor of the second conductivity type across the first and second transistors.

16. The method of claim 11, wherein modifying the control signal comprises pulling down the control signal to a voltage source.

17. The method of claim 16, wherein regulating the temporal voltage inequality comprises connecting a first terminal of a second control transistor of the second conductivity type to the control signal and a second terminal to the voltage source.

18. The method of claim 16, wherein the voltage source is a regulated voltage.

19. The method of claim 11, wherein
the temporal voltage inequality is an inequality between a second voltage difference and the first voltage difference, and
the second voltage difference is a difference between the first BL and the second BL at the second instant.

20. A system comprising:
a processor configured to execute a program; and
a memory configured to store the program and comprising a memory circuit comprising:
a first circuit configured to regulate a first voltage difference between a first bit line (BL) and a second BL at a first instant in a first offset cancellation (OC) interval within an OC period, the first voltage difference being associated with a first threshold mismatch between two or more transistors of a first conductivity type in a first part of a sense amplifier; and
a second circuit configured to regulate a temporal voltage inequality at a second instant in a second OC interval within the OC period, the temporal voltage difference being associated with a second threshold mismatch between two or more transistors of a second conductivity type in a second part of the sense amplifier,
wherein the second circuit regulating the temporal voltage inequality includes modifying a control signal that controls the second part.
